(19) United States
(12) Patent Application Publication
(10) Pub. No.: US 2017/0194102 A1
(43) Pub. Date: Jul. 6, 2017

(54) SOLAR CELL MODULE WITH PEROVSKITE LAYER

(71) Applicant: CPC CORPORATION, TAIWAN, Kaohsiung City (TW)

(72) Inventors: KUAN-CHIEH HUANG, KAOHSIUNG CITY (TW); LI-CHUNG LAI, KAOHSIUNG CITY (TW)

(21) Appl. No.: 15/395,255

(22) Filed: Dec. 30, 2016

(30) Foreign Application Priority Data
Dec. 31, 2015 (TW) 104144663

(51) Int. Cl. H01G 9/20; H01L 51/00; H01L 25/04; H01L 51/44; H01L 51/42

(52) U.S. Cl. CPC H01G 9/2013; H01L 51/448; H01L 51/445; H01L 51/424; H01L 25/047; H01L 51/0096; H01L 51/0077

(57) ABSTRACT

A solar cell module with a perovskite layer is revealed. The solar cell module includes a transparent substrate with a light incident surface and a surface opposite to the light incident surface. A plurality of solar cell units is disposed on the surface and each solar cell includes a transparent conductive layer, a first carrier transport layer, a perovskite layer and a second carrier transport layer. An insulation layer is not only located between the adjacent solar cell units but also covered over the solar cell units. A plurality of conductors is used for electrical connection of the plurality of solar cell units in series. Thus the solar cell module has better open circuit voltage and higher stability owing to connection way of the solar cell units in series and the insulation layer.

### BACKGROUND OF THE INVENTION

Field of the Invention

The present invention relates to a solar cell module with a perovskite layer, especially to a solar cell module formed by a plurality of perovskite solar cell units and the solar cell units are electrically connected in series at once by a plurality of conductors. Thereby the solar cell module has better open circuit voltage and higher stability.

Description of Related Art

The use of large amount of non-renewable resource by human being cause serious damage to the environment and also affects living organisms in the biosphere. In recent years, various countries now develop and introduce renewable energy resources owing to environmental consciousness. Among these renewable energy resources, solar energy has become one of the development priorities of renewable energy technology due to unlimited source of energy and low pollution.

Among a series of new generation solar cells, perovskite solar cells with perovskite photoactive layer are the most promising. The perovskite structure has broad absorption spectrum and high absorption coefficient. This is beneficial to high short circuit current and better photoelectric conversion efficiency.

Refer to Taiwanese Pat. No. 1485154 B “HYBRID ORGANIC SOLAR CELL WITH PEROVSKITE STRUCTURE AS ABSORPTION MATERIAL AND MANUFACTURING METHOD”, Taiwanese Pat. No. 1474992 B “METHOD FOR PREPARING PEROVSKITE THIN FILM AND SOLAR CELL”, US Pub. App. No. 20150200377 A1 and US Pub. App. No. 20150228415 A1, all relate to perovskite solar cells. However, the open circuit voltage of the solar cell in these prior arts is only 1.05V. The voltage level is too low to drive electronic components such as an LED (light emitting diode) with a forward voltage of 3V. Moreover, connection of solar cells available now in series requires other techniques or machines. Now the solar cells are usually connected in series by labor. For example, the connection process should be repeated four times manually if users intend to connect five solar cells in series. The above method not only increases impedance, the products produced by the method also have defects easily. Moreover, perovskite structure of the solar cell is easy to have decomposition and leakage out of the solar cell after contact with water. The perovskite solar cell has shortcomings of low stability, low safety and low photoelectric conversion efficiency.

Thus there is room for improvement and there is a need to provide a novel perovskite solar cell module.

### SUMMARY OF THE INVENTION

Therefore it is a primary object of the present invention to provide a solar cell module with a perovskite layer in which a plurality of solar cell units are protected by an insulation layer and connected in series by a plurality of conductors at once. The solar cell module of the present invention not only has lower impedance than the conventional solar cells connected in series by labor, but also provides better open circuit voltage and stability.

In order to achieve the above object, a solar cell module with a perovskite layer according to the present invention includes a transparent substrate, a plurality of solar cell units, an insulation layer, and a plurality of conductors. The transparent substrate includes a light incident surface and a surface opposite to the light incident surface. The solar cell units are arranged at the surface of the transparent substrate. Each solar cell unit consists of a transparent conductive layer, a first carrier transport layer, a perovskite layer and a second carrier transport layer. The insulation layer is not only located between the adjacent solar cell units but also covered over all the solar cell units. The conductors are used for electrical connection of the plurality of solar cell units in series.

The transparent substrate can be either a rigid substrate or a flexible substrate.

The rigid substrate or the flexible substrate is made from glass, sapphire, polyethylene terephthalate (PET), or polyethylene naphthalate (PEN).

The materials for the transparent conductive layer include Indium Tin Oxide (ITO), Indium-doped Zinc Oxide (IZO), Al-doped Zinc Oxide (AZO), and Florine doped Tin Oxide (FTO). The first carrier transport layer is made from PEDOT(poly(3,4-ethylenedioxythiophene)), PSS(poly(styrene sulfonate)), PTPD (poly[N,N′-bis(4-butylphenyl)-N,N′-bis(phenyl)-benzidine]), nickel oxide, caesium carbonate, zirconium oxide, or titanium dioxide.

The perovskite layer is made from material selected from CH₃NH₃PbI₃, CH₃NH₃PbBr₃, CH₃NH₃PbCl₃, CH₃NH₃PbI₂Br, CH₃NH₃PbI₂Cl, CH₃NH₃PbIBr₂, CH₃NH₃PbICl₂, CH₃NH₃SnI₃ and HC(NH₂)₂PbI₃.

The second carrier transport layer is made from fullerene (C₆₀), PC₆₁BM([6,6]-phenyl-C61-butyric acid methyl ester), ICBA(indene-C60 bisadduct), PC₇₁BM([6,6]-phenyl C71 butyric acid methyl ester), Spiro-MeOTAD(2,2′,7,7′-Tetrakis[N,N-di(4-methoxyphenyl)amino]-9,9′-spirobifluorene), lithium fluoride, zinc oxide, tungsten trioxide, molybdenum trioxide or vanadium pentoxide.

The insulation layer is made from silicon dioxide, alumina, silicon nitride, or aluminum nitride.

The conductor is made from aluminum, silver, gold or calcium.

The insulation layer is distributed between the adjacent conductors and lateral surfaces of the solar cell module with the perovskite layer.

In the present invention, the solar cell units are connected in series at once by the conductors. The insulation layer prevents decomposition of the perovskite layer caused by contact with water in the atmosphere. Thus reduction of photovoltaic conversion efficiency and instability can further be avoided. The shortcomings of the perovskite solar cells available now including low open circuit voltage and high impedance caused by manual connection in series can be overcome. The industrial applicability of the perovskite solar cells is significantly improved.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a longitudinal sectional view of an embodiment according to the present invention;

FIG. 2 is a schematic drawing showing an embodiment according to the present invention.

### DETAILED DESCRIPTION OF THE PREFERRED EMBODIMENT

In order to learn functions and features of the present invention, please refer to the following embodiments with figures and detailed descriptions.

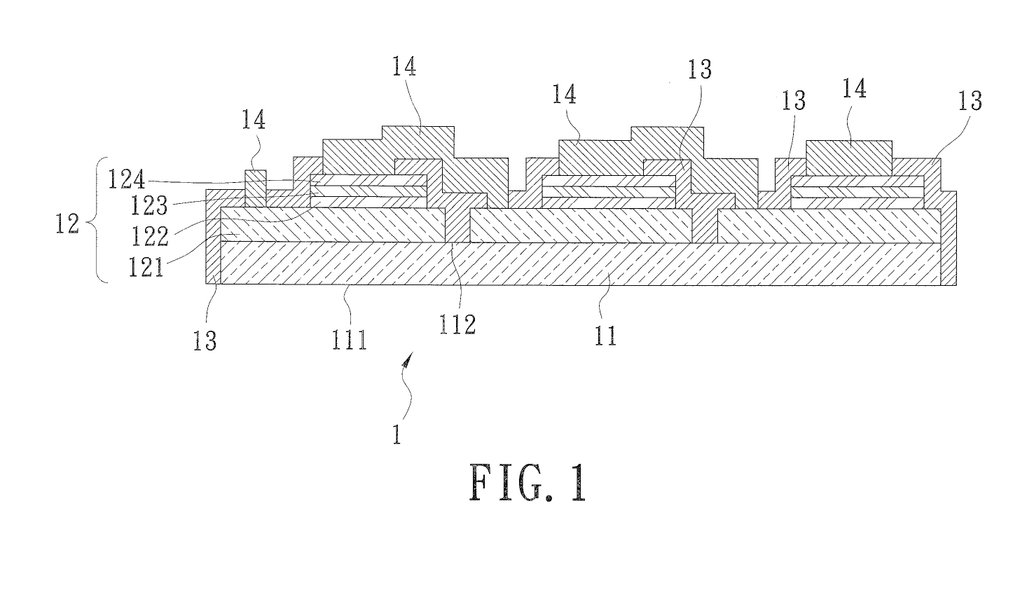

Refer to FIG. 1, a solar cell module with a perovskite layer 1 of the present invention includes a transparent substrate 11, a plurality of solar cell units 12, an insulation layer 13, and a plurality of conductors 14.

The transparent substrate 11 includes a light incident surface 111 and a surface 112 opposite to the light incident surface 111. The transparent substrate 11 can be either a rigid substrate or a flexible substrate made from one of the following materials: glass, sapphire, polyethylene terephthalate (PET), and polyethylene naphthalate (PEN).

The solar cell units 12 are arranged at the surface 112 of the transparent substrate 11. Each solar cell unit 12 consists of a transparent conductive layer 121, a first carrier transport layer 122, a perovskite layer 123 and a second carrier transport layer 124. The materials for the transparent conductive layer 121 include Indium Tin Oxide (ITO), Indium-doped Zinc Oxide (IZO), Al-doped Zinc Oxide(AZO), and

Florine doped Tin Oxide (FTO). The first carrier transport layer 122 is made from PEDOT(poly(3,4-ethylenedioxythiophene)), PSS(poly(styrene sulfonate)), PTPD (poly[N,N′-bis(4-butylphenyl)-N,N′-bis(phenyl)-benzidine]), nickel oxide, caesium carbonate, zirconium oxide, or titanium dioxide. The perovskite layer 123 is made from material selected from CH₃NH₃PbI₃, CH₃NH₃PbBr₃, CH₃NH₃PbCl₃, CH₃NH₃PbI₂Br, CH₃NH₃PbI₂Cl, CH₃NH₃PbIBr₂, CH₃NH₃PbICl₂, CH₃NH₃SnI₃ and HC(NH₂)₂PbI₃. The second carrier transport layer 124 is made from fullerene (C₆₀), PC₆₁BM([6,6]-phenyl-C61-butyric acid methyl ester), ICBA(indene-C60 bisadduct), PC₇₁BM([6,6]-phenyl C71 butyric acid methyl ester), Spiro-MeOTAD(2,2′,7,7′-Tetrakis[N,N- di(4-methoxyphenyl)amino]-9,9′-spirobifluorene), lithium fluoride, zinc oxide, tungsten trioxide, molybdenum trioxide or vanadium pentoxide.

The insulation layer 13 is not only located between the adjacent solar cell units 12 but also covered over all the solar cell units 12. The material for the insulation layer 13 is selected from the group consisting of silicon dioxide, alumina, silicon nitride, and aluminum nitride. The insulation layer 13 is also distributed between the adjacent conductors 14 and lateral surfaces of the solar cell module with the perovskite layer 1.

The conductors 14 are used to electrically connect the plurality of solar cell units 12 in series and are made from aluminum, silver, gold or calcium.

Please refer to the following embodiment for learning applications of the present invention.

Refer to FIG. 1, a longitudinal section of an embodiment of the present invention is revealed. A method for producing a solar cell module with a perovskite layer 1 of the present invention includes a plurality of steps.

Step 1: producing a plurality of solar cell units 12. Each solar cell unit 12 is manufactured by sputtering of a transparent conductive layer 121 over a transparent substrate 11. A first carrier transport layer 122 is formed on the transparent conductive layer 121 by spin coating, sputtering or evaporation. A perovskite layer 123 is formed on the first carrier transport layer 122 by spray coating, spin coating, sputtering or evaporation. A second carrier transport layer 124 is formed on the perovskite layer 123 by sputtering or evaporation.

Step 2: using material selected from the group consisting of silicon dioxide, alumina, silicon nitride, and aluminum nitride to form an insulation layer 13 on the second carrier transport layer 124 of the solar cell units 12 by PECVD, sputtering, electron beam gun (E-gun) evaporation or atomic layer chemical vapor deposition (ALCVD).

Step 3: using material selected from the group consisting of aluminum, silver, gold and calcium to form a plurality of conductors 14 on the insulation layer 13 over the solar cell units 12 at once. Thus the solar cell units 12 are connected in series by the conductors 14.

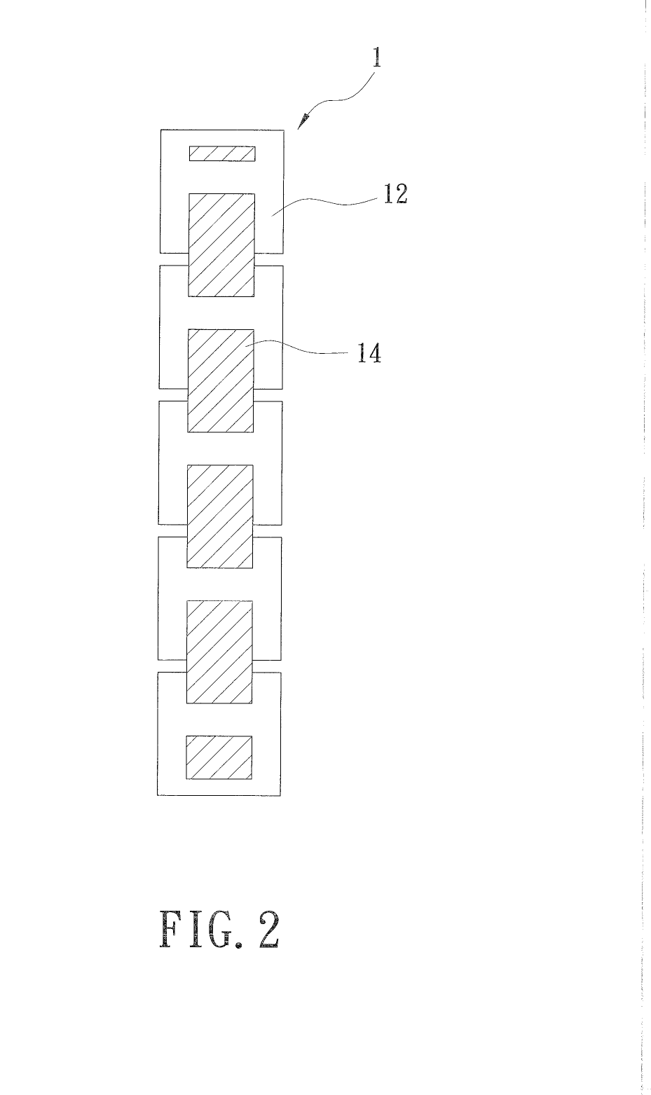

In an embodiment of the present invention, there are five solar cell units 12 produced by the method mentioned above and connected in series. Refer to FIG. 2, the five solar cell units 12 are electrically connected in series by the plurality of conductors 14 to form a solar cell module with a perovskite layer 1. Thus open circuit voltage is improved effectively. Compared with conventional connection way that repeats the connection process for at least four times to connect the five solar cell units in series manually, the present invention only needs to connect the five solar cell units in series by one connection process. The series impedance is dramatically reduced. The present invention is more suitable for industrial applications.

Compared with the techniques available now, the present invention has the following advantages:

1. The insulation layer prevents the decomposition of the perovskite layer caused by contact with water in atmosphere. Thus the reduced photoelectric conversion efficiency, instability and lower safety problems of the solar cell available now have been solved.

2. The design of conductors used for connection of solar cell units in series can not only increase the open circuit voltage of the solar cell module, but also solve the problem of low output voltage from a single solar cell and high impedance resulted from connection by labor.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

What is claimed is:

1. A solar cell module with a perovskite layer comprising:
a transparent substrate having a light incident surface and a surface opposite to the light incident surface;
a plurality of solar cell units arranged at the surface of the transparent substrate;
an insulation layer that is disposed between the adjacent solar cell units and covered over all the solar cell units; and
a plurality of conductors used for electrical connection of the plurality of solar cell units in series;
wherein each of the solar cell units includes a transparent conductive layer, a first carrier transport layer, a perovskite layer and a second carrier transport layer

2. The device as claimed in claim 1, wherein the transparent substrate is selected from the group consisting of a rigid substrate and a flexible substrate.

3. The device as claimed in claim 2, wherein the rigid substrate or the flexible substrate is made from material selected from the group consisting of glass, sapphire, polyethylene terephthalate (PET), and polyethylene naphthalate (PEN).

4. The device as claimed in claim 1, wherein the transparent conductive layer is made from material selected from the group consisting of Indium Tin Oxide (ITO), Indium-doped Zinc Oxide (IZO), Al-doped Zinc Oxide(AZO), and Florine doped Tin Oxide (FTO); the first carrier transport layer is made from material selected from the group consisting of PEDOT(poly(3,4-ethylenedioxythiophene)), PSS(poly(styrene sulfonate)), PTPD (poly[N,N′-bis(4-butylphenyl)-N,N′-bis(phenyl)-benzidine], nickel oxide, caesium carbonate, zirconium oxide, and titanium dioxide.

5. The device as claimed in claim 1, wherein the perovskite layer is made from material selected from the group consisting of CH₃NH₃PbI₃, CH₃NH₃PbBr₃, CH₃NH₃PbCl₃, CH₃NH₃PbI₂Br, CH₃NH₃PbI₂Cl, CH₃NH₃PbIBr₂, CH₃NH₃PbICl₂, CH₃NH₃SnI₃ and HC(NH₂)₂PbI₃.

6. The device as claimed in claim 1, wherein the second carrier transport layer is made from material selected from the group consisting of fullerene (C₆₀), PC₆₁BM([6,6]-phenyl-C61-butyric acid methyl ester), ICBA(indene-C60 bisadduct), PC₇₁BM([6,6]-phenyl C71 butyric acid methyl ester), Spiro-MeOTAD(2,2′,7,7′-Tetrakis [N,N-di(4-methoxyphenyl)amino]-9,9′-spirobifluorene), lithium fluoride, zinc oxide, tungsten trioxide, molybdenum trioxide and vanadium pentoxide.

7. The device as claimed in claim 1, wherein the insulation layer is made from material selected from the group consisting of silicon dioxide, alumina, silicon nitride, and aluminum nitride.

8. The device as claimed in claim 1, wherein the conductor is made from material selected from the group consisting of aluminum, silver, gold and calcium.

9. The device as claimed in claim 1, wherein the insulation layer is distributed between the adjacent conductors and lateral surfaces of the solar cell module with the perovskite layer.
